(19) United States
(12) Patent Application Publication
(10) Pub. No.: US 2016/0276985 A1
(43) Pub. Date: Sep. 22, 2016

(54) AMPLIFIER APPARATUS AND METHOD

(71) Applicant: TELEFONAKTIEBOLAGET L M ERICSSON (PUBL), Stockholm (SE)

(72) Inventors: Christian FAGER, Mölnlycke (SE); Mustafa ÖZEN, Göteborg (SE)

(21) Appl. No.: 15/029,506

(22) PCT Filed: Oct. 16, 2013
(86) PCT No.: PCT/EP2013/071631

§ 371 Date: Apr. 14, 2016

(51) Int. Cl. H03F 1/32; H03F 3/19; H03F 3/21; H03F 1/02

(52) U.S. Cl. CPC H03F 1/32; H03F 1/0288; H03F 3/19; H03F 3/211; H03F 2201/3203; H03F 2203/21142; H03F 2200/451

(57) ABSTRACT

An amplifier arrangement for optimising efficiency at a peak power level and a back-off power level comprises a main power amplifier provided in a main branch for receiving a first signal, the main power amplifier being configured to operate in a class-B mode of operation. An auxiliary power amplifier is provided in an auxiliary branch for receiving a second signal, the auxiliary power amplifier being configured to operate in a class-C mode of operation. The main power amplifier and the auxiliary power amplifier are substantially matched in size. The first signal and the second signal have a phase offset value θ that is selected in relation to a particular back-off power level γ of operation, wherein 0<θ<180°. A combining network is configured to couple the output signals of the main and auxiliary amplifiers to an output node of the amplifier arrangement such that the output of the auxiliary power amplifier load modulates the output of the main power amplifier. The circuit element values of the combining network are derived based on the selected phase shift value θ and the related back-off power level γ at which the amplifier arrangement is optimised for efficiency.

### TECHNICAL FIELD

The present invention relates to an amplifier apparatus and method, and in particular to a Doherty amplifier arrangement and method.

### BACKGROUND

Modern communication systems often employ signals with high peak to average power ratio (PAPR) to improve the spectral efficiency. The efficiency of a traditional class-AB power amplifier, however, is rapidly degraded when the output power is backed off from its maximum value. The efficiency at a back-off level may, however, be improved by incorporating the power amplifier into special transmitter or power amplifier architectures. For example, one such architecture is an amplifier configured to provide Doherty modulation, as disclosed in a paper by W. H. Doherty, “A New High Efficiency Power Amplifier for Modulated Waves,” Proceedings of the Institute of Radio Engineers, vol. 24, no. 9, pp. 1163-1182, September 1936. Another example is the use of out-phasing modulation, also known as the Chireix technique, as described in a paper by H. Chireix, “High Power Outphasing Modulation, “Proceedings of the Institute of Radio Engineers, vol. 23, no. 11, pp. 1370-1392, November 1935. Yet another example is the use of dynamic load modulation, as described in a paper by F. H. Raab, “High-efficiency linear amplification by dynamic load modulation,” IEEE MTT-S International Microwave Symposium Digest, vol. 3, pp. 1717-1720, 8-13 June 2003.

In a Doherty configuration, the fundamental principle of Doherty operation is to modulate the impedance seen by the main power amplifier via active current injection using an auxiliary power amplifier. Based on this principle, the peak efficiency can be maintained both at a peak power and at an average power level of the signal, for example at a back-off level of 6 dB below the peak level.

The classical Doherty configuration consists of two identical class-B biased devices, the outputs of which are combined with a quarter wave transformer, as disclosed in the paper by Doherty noted above. Both of the inputs to the identical class-B biased devices are controlled individually to achieve the required current profiles. Such a configuration may provide the ideal peak efficiency (78.5%) of a class-B power amplifier at a peak power level and at a back-off level of 6 dB lower than the peak power level. However, modern communications signals often employ signals with PAPRs of even higher than 6 dB.

An asymmetrical Doherty power amplifier is a generalized version of the classical configuration where the second efficiency peak can be placed at any desired back-off level, for example as described in a paper by M. Iwamoto, et. al., “An extended Doherty amplifier with high efficiency over a wide power range,” IEEE Transactions on Microwave Theory and Techniques, vol. 49, no. 12, pp. 2472-79, December 2001. This back-off level will be referred to hereinafter with the symbol γ throughout this document.

The asymmetrical Doherty arrangement uses the same load network topology as the classical configuration, but with different circuit element values. Furthermore, for the asymmetrical Doherty arrangement, the ratio of the device peripheries (i.e. sizes) of the auxiliary and main transistor devices scales according to the back-off level γ. This ratio is given by:

α=\sqrt{γ}−1

For instance, α=1 for γ=6 dB, corresponding to the classical Doherty configuration, and 2.98 for γ of 12 dB, meaning that the auxiliary transistor should have a size which is almost three times larger (at maximum current) compared to the main transistor. It is noted that the derivation of the equation above assumes that both main and auxiliary amplifiers are class-B biased.

The ideal Doherty theory used above assumes individual control of the main and auxiliary transistor branches. This independent control can be achieved in the digital domain, but at the cost, however, of requiring two complete up-converter stages.

Another approach, which is used in practice, is to use an analog input signal splitter. In this case the main amplifier is biased for class-B operation while the auxiliary amplifier is biased for class-C operation. By choosing an appropriate class-C bias point, the auxiliary amplifier can be made to shut off automatically at an associated back-off level of γ dB. Such a single input Doherty is thus self-managing and therefore has a very simple configuration from a system point of view. It is thus a very suitable candidate for low/medium power systems, such as small base stations, microwave links and handset transmitters.

However, on the other hand, the gain of the class-C amplifier reduces rapidly in relation to the back-off level in a single input Doherty power amplifier. The overall power added efficiency (PAE) therefore degrades significantly as the amount of back-off increases. In particular, the class-C amplifier shuts off at γ dB back-off and the input power delivered to it is then just wasted. It is noted that, PAE degradation will be more severe for larger values of back-off γ, since a larger device periphery class-C amplifier will be needed (which hence wastes more power when shut off and having power delivered to it). It is also noted that the class-C current waveform contains less fundamental tone component than the class-B waveform, which was assumed when deriving the expression of α. The ratio between the auxiliary and main transistor peripheries will therefore become even higher than given by α, thus further amplifying this problem.

The use of a very large class-C amplifier also causes practical limitations on realization of the analog input signal splitter. For instance, the power division ratio (Pᵢₙ₋ₐᵤₓ/Pᵢₙ₋ₘₐᵢₙ) of the splitter becomes 7 dB for a back-off level γ of 9 dB, for example as explained in a paper by Paolo Colantonio, et. al., “The AB-C Doherty power amplifier. Part I: Theory”, International Journal of RF and Microwave Computer-Aided Engineering, vol. 19, no. 3, pp. 293-422, 2009.

In general, if the power division ratio of a splitter is very uneven, the resulting transmission lines become very thin and/or thick, putting a practical limitation on the realization of the splitter. In some cases, attenuators might even be required to achieve the appropriate power division ratio, further degrading the PAE, for example as described in a paper by Jangheon Kim, et al., “Optimum operation of asymmetrical-cells-based linear Doherty power Amplifiers-uneven power drive and power matching,” IEEE Transactions on Microwave Theory and Techniques, vol. 53, no. 5, pp. 1802-1809, May 2005.

A further complication is that, when considering designs using discrete transistors, the number of available device sizes from semiconductor manufacturers is typically limited. It might therefore occur that the required device sizes are not available, in particular if the ratio of device peripheries is a non-integer value. In such a scenario a practical realization of a Doherty power amplifier becomes quite empirical, therefore limiting the achievable performance.

### SUMMARY

It is an aim of the present invention to provide an amplifier arrangement and method which obviate or reduce at least one or more of the disadvantages mentioned above.

According to a first aspect of the present invention there is provided an amplifier arrangement for optimising efficiency at a peak power level and a back-off power level. The amplifier arrangement comprises a main power amplifier provided in a main branch for receiving a first signal, the main power amplifier being configured to operate in a class-B mode of operation. An auxiliary power amplifier is provided in an auxiliary branch for receiving a second signal, the auxiliary power amplifier being configured to operate in a class-C mode of operation. The main power amplifier and the auxiliary power amplifier are substantially matched in size. The received first and second signals have a phase offset value that is selected in relation to a particular back-off power level of operation, wherein 0<θ<180°. A combining network is configured to couple the output signals of the main and auxiliary amplifiers to an output node of the amplifier arrangement such that the output of the auxiliary power amplifier load modulates the output of the main power amplifier, wherein the circuit element values of the combining network are derived based on the selected phase shift value and the related back-off power level at which the amplifier arrangement is optimised for efficiency.

According to another aspect of the present invention there is provided a method of optimising the efficiency of an amplifier arrangement at a peak power level and a back-off power level. The method comprises the steps of amplifying a first signal using a main power amplifier configured to operate in a class-B mode of operation, and amplifying a second signal using an auxiliary power amplifier configured to operate in a class-C mode of operation, wherein the main power amplifier and the auxiliary power amplifier are substantially matched in size, and wherein the first signal and the second signal have a phase offset value that is selected in relation to a particular back-off power level of operation, wherein 0<θ<180°. The method comprises the step of combining the output signals of the main and auxiliary amplifiers to an output node of the amplifier arrangement using a combining network, such that the output of the auxiliary power amplifier load modulates the output of the main power amplifier, wherein the circuit element values of the combining network are derived based on the selected phase shift value and the related back-off power level at which the amplifier arrangement is optimised for operation.

### BRIEF DESCRIPTION OF THE DRAWINGS

For a better understanding of examples of the present invention, and to show more clearly how the examples may be carried into effect, reference will now be made, by way of example only, to the following drawings in which:

FIG. 1 shows an amplifier arrangement according to an embodiment of the present invention;

FIG. 2 shows a method according to an embodiment of the present invention;

FIG. 3 shows an example of a two-port combining network used to derive parameters of an amplifier arrangement according to an embodiment of the present invention;

FIG. 4a shows an example of a corresponding three port network used to realise the parameters derived in FIG. 3, according to an embodiment of the present invention;

FIG. 4b shows an example realization of a combining network of an embodiment of the invention using lumped components;

FIG. 5a shows the drain efficiency of an amplifier according to an embodiment of the present invention for a back-off value of 7.5 dB;

FIG. 5b shows the drain efficiency of an amplifier according to an embodiment of the present invention for a back-off value of 9 dB;

FIG. 5c shows the drain efficiency of an amplifier according to an embodiment of the present invention for a back-off value of 11 dB;

FIG. 5d shows the drain efficiency of an amplifier according to an embodiment of the present invention for a back-off value of 13 dB;

FIG. 6a shows the load lines of a main amplifier of an embodiment of the present invention, in an example where the back-off value γ is 13 dB and the phase angle θ is 48°;

FIG. 6b shows the load lines of an auxiliary amplifier of an embodiment of the present invention, in an example where the back-off value γ is 13 dB and the phase angle θ is 48°;

FIG. 7a shows the normalized gain of an amplifier according to an embodiment of the present invention, in an example where the back-off value γ is 7 dB (compared to the normalized gain of a conventional asymmetrical Doherty amplifier shown in dashed lines);

FIG. 7b shows the normalized gain of an amplifier according to an embodiment of the present invention, in an example where the back-off value γ is 9 dB (compared to the normalized gain of a conventional asymmetrical Doherty amplifier shown in dashed lines);

FIG. 7c shows the normalized gain of an amplifier according to an embodiment of the present invention, in an example where the back-off value γ is 11 dB (compared to the normalized gain of a conventional asymmetrical Doherty amplifier shown in dashed lines);

FIG. 7d shows the normalized gain of an amplifier according to an embodiment of the present invention, in an example where the back-off value γ is 13 dB (compared to the normalized gain of a conventional asymmetrical Doherty amplifier shown in dashed lines);

FIG. 8 shows an example of a load network topology according to an embodiment of the present invention;

FIG. 9 compares the gain of an amplifier according to an embodiment of the present invention with a conventional asymmetrical Doherty amplifier; and

FIG. 10 compares the power added efficiency of an amplifier according to an embodiment of the present invention with a conventional asymmetrical Doherty amplifier.

### DETAILED DESCRIPTION

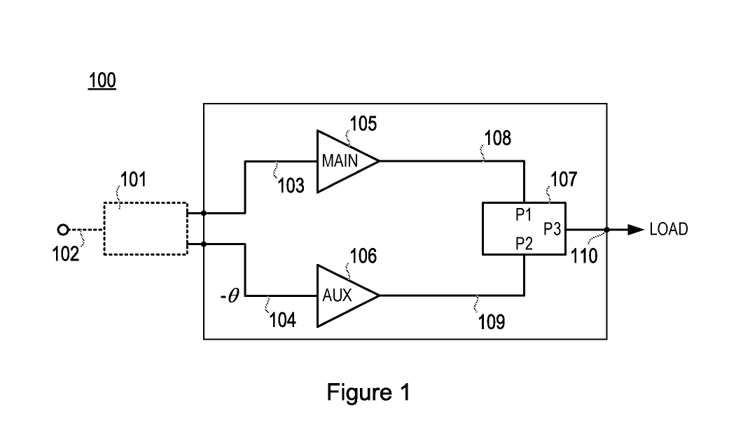

FIG. 1 shows an amplifier arrangement 100 according to an embodiment of the present invention, for optimising efficiency at a peak power level and a back-off power level γ. The amplifier arrangement 100 comprises a main power amplifier 105 provided in a main branch for receiving a first signal 103. The main power amplifier is configured to operate in a class-B mode of operation. The amplifier arrangement 100 also comprises an auxiliary power amplifier 106 provided in an auxiliary branch for receiving a second signal 104. The auxiliary power amplifier is configured to operate in a class-C mode of operation.

It is noted that the first signal 103 and the second signal 104 may be received, for example, from a signal splitting device that in turn receives an input signal and splits the input signal into the first signal 103 for the main branch and the second signal 104 for the auxiliary branch of the amplifier arrangement. Such a signal splitting device may comprise and analog splitter or a digital splitter.

The main power amplifier 105 and the auxiliary power amplifier 106 are substantially matched in size. For example, the main power amplifier and auxiliary power amplifier are symmetrical or equally sized, that is, the periphery of the devices are equally matched, and have matching parameter values, such as matching current and voltage ratings. As a further example the main power amplifier 105 and the auxiliary power amplifier 106 may be matched in size by the transistor technology, or the device structure being the same for both cells (for example whereby laterally diffused metal oxide semiconductor (LDMOS) transistors with matching current and voltage parameters are used for an implementation). It is noted that other technologies and techniques can be used to provide matching amplifiers.

The received first and second signals 103, 104 have a phase offset value θ, wherein the phase offset value is selected in relation to a particular back-off power level γ of operation, wherein 0<θ<180°. For example, the second signal may be made to lag the first signal by the phase shift θ, although it is noted that the embodiments of the invention are also intended to cover the phase shift being provided in the opposite manner, whereby the first signal lags the second signal.

A combining network 107 is configured to couple the output signals 108, 109 of the main and auxiliary amplifiers 105, 106 to an output node 110 of the amplifier arrangement. The circuit element values of the combining network 107 are derived based on the selected phase shift value θ and the related back-off power level γ at which the amplifier arrangement is optimised for efficiency.

As such, rather than using a fixed 90° phase offset value as used in a conventional Doherty amplifier arrangement, the embodiments of the invention enable the phase offset value to be used as a design parameter for configuring the network for optimised efficiency at a particular back-off level as well as a peak power level. Using a non-fixed 90° phase angle, but instead a selectable value which is selected in relation to a particular back-off level γ, this therefore provides a further design parameter which can be used to enhance the load modulation of the auxiliary power amplifier, thus improving efficiency at the back-off power level and the peak power level. The circuit element values of the combining network 107 are also based on the particular back-off level γ and the phase shift value θ.

Thus, according to embodiments of the invention, an active load modulation based power amplifier topology is developed that uses substantially matched or symmetrical (i.e. equally sized) devices for main and auxiliary branches or cells of the amplifier arrangement, independent of the back-off level γ that is required. It is assumed that both amplifiers deliver maximum possible output power at a peak power level and that the current/voltage swings available from both devices are fully utilized.

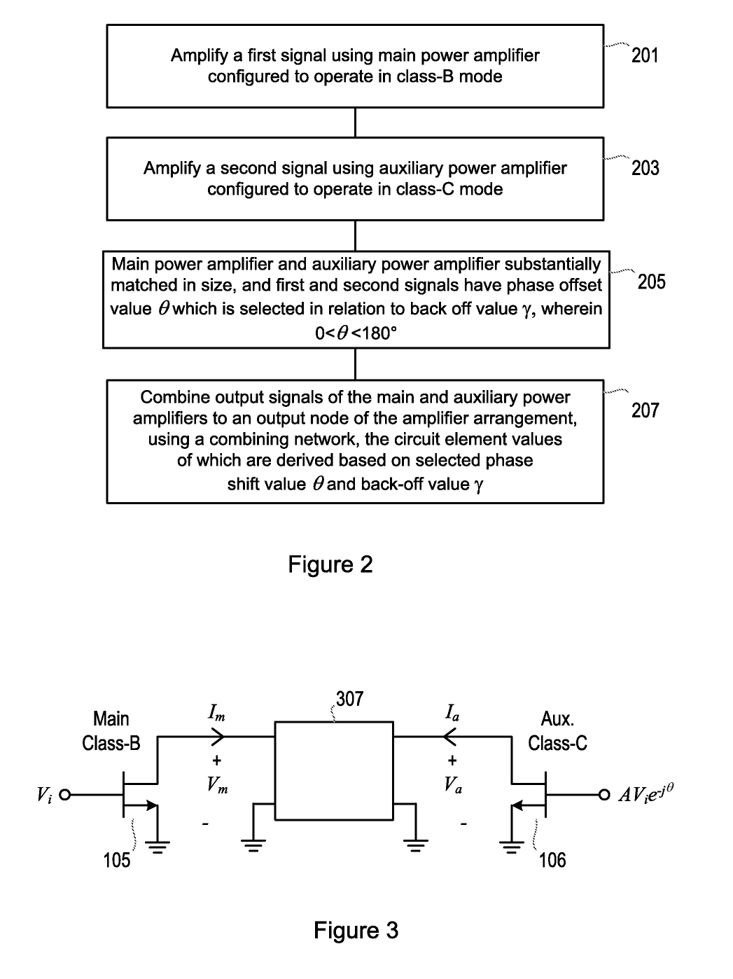

FIG. 2 shows a method according to an embodiment of the present invention. In step 201 a first signal is amplified using a main power amplifier that is configured to operate in a class-B mode of operation. In step 203 a second signal is amplified using an auxiliary power amplifier that is configured to operate in a class-C mode of operation. The main amplifier and the auxiliary amplifier are substantially matched in size, and the first and second signals have a phase offset value θ which is selected in relation to a particular back-off value γ, wherein 0<θ<180°, step 205. The output signals of the main power amplifier and the auxiliary power amplifier are combined to an output node of the amplifier arrangement using a combining network, the circuit element values of which are derived based on the selected phase shift value θ and the back-off value γ, step 207.

Further details will be provided later in the application concerning how the circuit element values of the combining network are derived, According to embodiments of the invention, the combining network is synthesized using a black-box approach where the network parameters (circuit element values) are derived from the desired operating conditions. These conditions include:
an optimal load being presented to the class-B cell (main transistor/amplifier) at peak power level;
an optimal load being presented to the class-C cell (auxiliary transistor/amplifier) at peak power level; and
an optimal load being is presented to the class-B cell (main transistor/amplifier) at a desired back-off level, e.g. at PAPR of the signal.

An optimal load implies that the available voltage swing is fully utilized.

The use of symmetrical main and auxiliary amplifiers avoids the limitations of the asymmetrical Doherty concept mentioned in the background section. The embodiments of the invention have the advantage of providing higher gain and efficiency with a much simpler configuration, as will be explained in greater detail below.

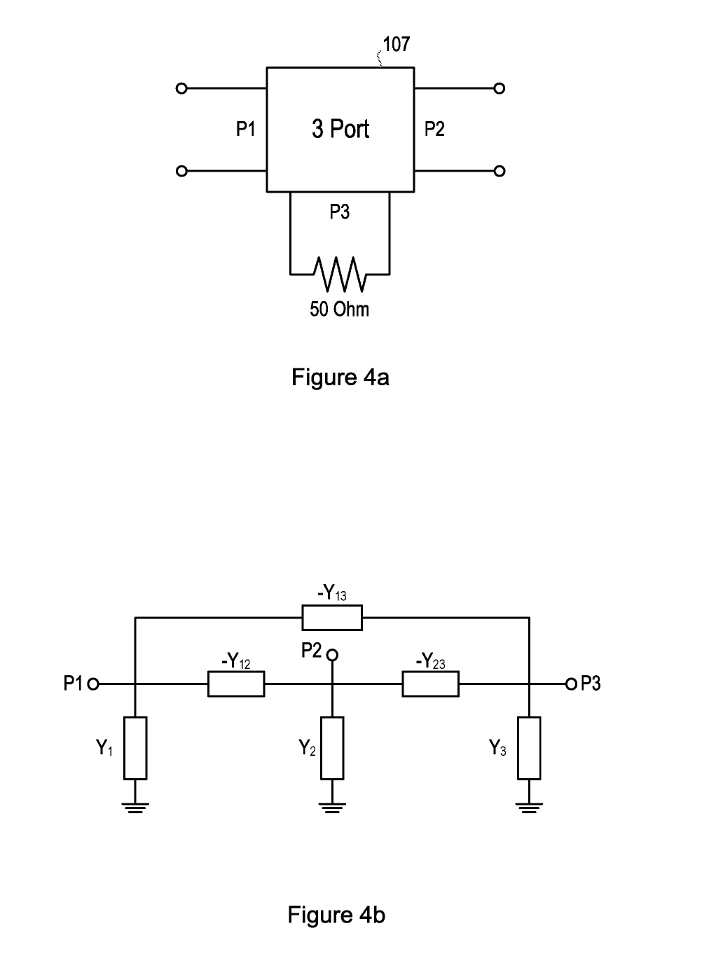

Mathematical derivations will be based on the schematic shown in FIG. 3. The schematic of FIG. 3 consists of two equally sized transistors, representing the main power amplifier 105 and the auxiliary power amplifier 106 of FIG. 1, combined with a two port reciprocal network 307. The load resistance is thus included in the two-port network 307. After calculating the network parameters (which will be described in greater detail below), this intermediate two port network 307 is converted to an equivalent lossless reciprocal three port network, whose third port is terminated with the load resistance, as shown in FIG. 4a. The main power amplifier 105 is biased in class-B mode, while the auxiliary power amplifier 106 is biased in class-C mode, where its conduction angle, or gate bias, depends on the design parameter γ.

For the conventional Doherty power amplifier, the phase shift between the main and auxiliary drive signals is fixed at 90°. For the proposed symmetrical Doherty power amplifier according to embodiments of the invention, however, the phase shift between the drive signals, θ (see FIG. 3), is a design variable. An additional degree of freedom is thus created for the design that may be used to improve the efficiency degradation for the power levels between the peak power level and a back-off level γ.

First, definitions are given and then the network parameters are derived.

The current iₘ(vᵢ) flowing through the main device is defined as:

$${i}_{m} ( {v}_{i} ) = \{ \begin{matrix}{v}_{i} {I}_{max} sin φ , & 0 \leq φ \leq π \\ 0 , & otherwise\end{matrix}$$

where vᵢ is the input signal for the main amplifier, and 0≦vᵢ≦1 and φ=ωₒt.

The current iₐ(vᵢ) flowing through the class-C biased auxiliary amplifier is defined as:

$${i}_{a} ( {v}_{i} ) = \{ \begin{matrix}\frac{{I}_{max}}{1 - {v}_{bk}} ( {v}_{i} sin ( φ - θ ) - 1 ) + {I}_{max} , & {φ}_{x} \leq φ - θ \leq π - {φ}_{x} \\ 0 , & otherwise\end{matrix}$$

where φₓ=a sin v_{bk}/vi, and where v_{bk} represents the main input voltage, vi, level at which the output power is at the desired back-off level. It is noted that, by definition of the auxiliary current iₐ, the auxiliary amplifier turns off when the main input voltage level is at b_{bk}.

Since v_{bk} represents the input voltage level at which the output power is at the desired back-off, v_{bk} therefore depends on γ and is solved from the equations described below. Then the auxiliary current expression is defined in a way that, at this level, vᵢ=V_{bk}, the auxiliary current is zero during the whole RF cycle. It can therefore be appreciated that v_{bk} is not a setting in the circuit as such, but is a mathematical variable that depends on γ. The circuit parameters are derived in terms of v_{bk}, where v_{bk} is derived in terms of γ as mentioned previously.

It is noted that the conduction angle of the class-C amplifier at peak power then follows as:

φ_{c}=π−2 a sin(v_{bk})

It can be observed that, the auxiliary current phase lags the main current phase by θ degrees and iₐ turns off when vᵢ≦v_{bk} . The term v_{bk} will later be solved in terms of the back-off level γ, and also determines the gate bias of the class-C transistor.

In order to calculate network parameters of the combining network, currents at the fundamental tone have to be known. The fundamental tone Fourier component of the current iₘ flowing through the main amplifier follows as:

$${I}_{m} ( {v}_{i} ) = - {v}_{i} \frac{{I}_{max}}{2} {e}^{j \frac{π}{2}}$$

Similarly, the fundamental tone Fourier component of iₐᵤₓ follows as:

$${I}_{a} ( {v}_{i} ) = \frac{j {I}_{max} ( ( {e}^{j θ} - 2 ) {v}_{bk} \sqrt{1 - {( \frac{{v}_{bk}}{{v}_{i}} )}^{2}} + {v}_{i} {e}^{- j θ} a cos \frac{{v}_{bk}}{{v}_{i}} )}{π ( {v}_{bk} - 1 )}$$

As mentioned previously parameter v_{bk} depends on the design variable γ. In order to solve v_{bk} in terms of γ, the following equation is given from the fact that only the main amplifier is active at γ dB back-off from the peak output power level:

$$\frac{{P}_{out - m} {\vert}_{{v}_{i} = 1} + {P}_{out - a} {\vert}_{{v}_{i} = 1}}{{10}^{\frac{γ}{10}}} = {P}_{out - m} {\vert}_{{v}_{i} = {v}_{bk}} \\ where$$

$${P}_{out - a} = \frac{{V}_{BR} {I}_{a}}{4}$$

$$and$$

$${P}_{out - m} = \frac{{V}_{BR} {I}_{m}}{4} .$$

An analytical solution of v_{bk} from the equation above is somewhat cumbersome. A numerical solution for a given γ can, however, easily be found.

Following the analysis above the necessary components have been determined in order to calculate the network parameters.

Next, it will be explained how the network parameters are derived.

From the definition of a Z matrix:

$$[ \begin{matrix}{V}_{m} \\ {V}_{a}\end{matrix} ] = [ \begin{matrix}{Z}_{11} & {Z}_{12} \\ {Z}_{21} & {Z}_{22}\end{matrix} ] [ \begin{matrix}{I}_{m} \\ {I}_{a}\end{matrix} ]$$

It is noted that Z₁₂=Z₂₁ since the network is reciprocal.

It is noted that class-B and class-C amplifiers should preferably be terminated with purely real loads, thus the voltage and current components are in-phase. The first and second conditions mentioned above (i.e. presenting optimal load to the class-B main amplifier at peak power level, and presenting optimal load to the class-C auxiliary amplifier at peak power level) thus yield the following equations:

$$\frac{{V}_{BR}}{2} {e}^{j {β}_{{I}_{m}}} = {Z}_{11} {I}_{m} {\vert}_{{v}_{i} = 1} + {Z}_{12} {I}_{a} {\vert}_{{v}_{i} = 1} \\ \frac{{V}_{BR}}{2} {e}^{j {β}_{{I}_{a}}} = {Z}_{12} {I}_{m} {\vert}_{{v}_{i} = 1} + {Z}_{22} {I}_{a} {\vert}_{{v}_{i} = 1}$$

where V_{BR} is the breakdown voltage of the respective transistors (being the same since the transistors are symmetrical) and and β_{I}_{ₘ} and β_{I}_{ₐ} are phase angles of Iₘ and Iₐ, respectively.

The third condition mentioned above (i.e. providing optimal matching of the class-B amplifier at a back-off level of γ dB) yields to the following equality, noting that Iₐ is then equal to zero:

$$\frac{{V}_{BR}}{2} {e}^{j {β}_{Im}} = {Z}_{11} {I}_{m} {\vert}_{{v}_{i} = {v}_{bk}}$$

This results in having three equations and three unknowns to be solved. The solution set thus follows as:

$${Z}_{11} = \frac{{V}_{BR}}{2 {v}_{bk} \vert {I}_{m} \vert}$$

$${Z}_{12} = \frac{{e}^{j θ} ( {v}_{bk} - 1 ) {V}_{BR}}{2 {v}_{bk} \vert {I}_{a} \vert}$$

$${Z}_{22} = \frac{{V}_{BR} ( - {e}^{j 2 θ} \vert {I}_{m} \vert ( {v}_{bk} - 1 ) + {v}_{bk} {I}_{a} )}{2 {v}_{bk} {\vert {I}_{a} \vert}^{2}}$$

It can be noted from the above that these expressions show that the two port network parameters are derived only in terms of transistor technology parameters and the design variables γ (back-off efficiency peak level) and θ (input signal phase shift between main and auxiliary branches).

Once the parameters have been derived, next, the two port network is converted to an equivalent lossless reciprocal three port network, as shown in FIG. 4a, for example corresponding to the combining network 107 of the embodiment of FIG. 1, whereby a first port P1 is coupled to the main amplifier, a second port P2 coupled to the auxiliary amplifier, and a third port P3 coupled to the load (corresponding to the system impedance). It is noted that the S-parameters S₁₁ to S₂₂ of the three-port network will be the same as that of two port network since the third port is terminated with the system impedance. Therefore, the unknowns are S₃₁, S₃₂, S₃₃ in the 3 port S-parameters matrix, noting that the S parameter matrix should be symmetrical due to reciprocal network assumption.

The following conditions hold for a lossless three port network:

$${\sum }_{n = 1}^{3} {\vert {S}_{ni} \vert}^{2} = 1$$

$${\sum }_{n = 1}^{3} {S}_{ns} {S}_{nr}^{*} = 0 s \neq r$$

The summations above expand to the following equations:

|S₁₁|²+|S₂₁|²+|S₃₁|²=1

|S₁₂|²+|S₂₂|²+|S₃₂|²=1

|S₁₃|²+|S₂₃|²+|S₃₃|²=1

S₁₃S*₁₁+S₂₃S*₂₁₊S₃₃S*₃₁=0

S₁₂S*₁₁+S₂₂S*₂₁₊S₃₂S*₃₁=0

S₁₁S*₁₂+S₂₁S*₂₂₊S₃₁S*₃₂=0

It can be observed that, amplitudes of the unknown S parameter terms follow from the first three equations. It can also be noted that the last two equations are the same. This can easily by proven by taking the complex conjugate of the other. There remain two equations and three unknown phases. Therefore, one of the phase terms should be arbitrary. This is explained by the fact that adding a 50 Ω transmission line to the third port does not affect the impedance levels in the circuit, but only introduces a phase-offset. The unknowns are therefore solved in terms of phase of S₃₁ that is denoted by ψ:

$${S}_{31} = \sqrt{1 - {\vert {S}_{11} \vert}^{2} - {\vert {S}_{21} \vert}^{2}} {e}^{j ψ}$$

$${S}_{32} = \frac{{S}_{11}^{*} {S}_{12} + {S}_{21}^{*} {S}_{22}}{\sqrt{1 - {\vert {S}_{11} \vert}^{2} - {\vert {S}_{21} \vert}^{2}}} {e}^{j ( π + ψ )}$$

$${S}_{33} = - \frac{\sqrt{1 - {\vert {S}_{12} \vert}^{2} - {\vert {S}_{22} \vert}^{2}} {S}_{21}^{*} {e}^{j ( {∠S}_{32} + ψ )}}{\sqrt{1 - {\vert {S}_{11} \vert}^{2} - {\vert {S}_{21} \vert}^{2}}} - {S}_{11}^{*} {e}^{j 2 ψ}$$

This conversion allows a check to be performed to determine if the lossless three port combining network 107 is physical or not. In other words, it can be determined whether the derived network parameters are ones that can be realized in a physical network, for example a physical lumped component network or a physical transmission line network.

It is noted that, for a physical reciprocal network, all |Sᵢⱼ| must be lower than unity. Depending on the value of the back-off level, γ, the resulting network parameters may be unphysical for some values of phase shift value θ. However, physical solutions are also found for a large range of phase shift values θ.

It is also noted that it is possible to realize a lumped element combiner network using synthesis methods, for example as described by Peter Linnér in “Unified Electronic Circuit Simulation: Theory and Design”, Section 5.5, Chalmers University of Technology, 2010, or by William C. Yengst in “Procedures of Modern Network Synthesis”, Collie-Macmillan Limited, 1964.

In FIG. 4b, an example of a lumped element schematic is given for the realization of the combiner where the component values are calculated from the three port Y parameters via the following equations:

$${Y}_{1} = - {Y}_{11} - {\sum }_{j = 1 , j \neq 1}^{n} {Y}_{1 j}$$

$${Y}_{2} = - {Y}_{22} - {\sum }_{j = 1 , j \neq 2}^{n} {Y}_{2 j}$$

$${Y}_{3} = - {Y}_{33} - {\sum }_{j = 1 , j \neq 3}^{n} {Y}_{3 j}$$

The resulting network can then be transformed to a transmission line network if desired. As such, embodiments of the invention are intended to embrace the combining network being implemented as lumped components, transmission lines, or a combination of both.

A description will now be provided in relation to the theoretical performance of an example of a symmetrical Doherty amplifier arrangement according to an embodiment of the present invention, whereby it is evaluated in terms of drain efficiency versus back-off and gain.

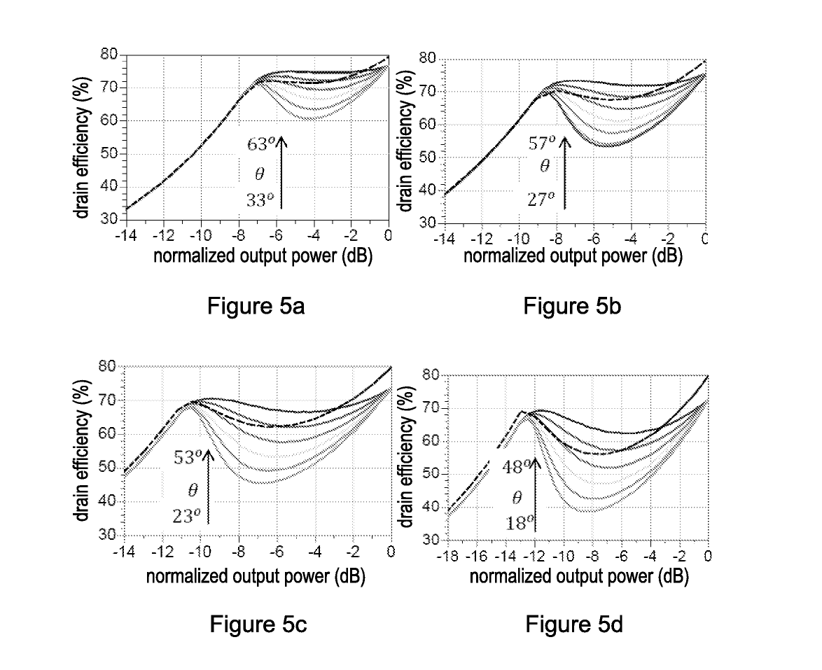

The theoretical derivation explained above ensures that the drain efficiency is maximized at the peak power and at a particular back-off level of γ dB. The exact efficiency profile versus back-off however depends on the selected phase shift value θ. In FIGS. 5a to 5d the drain efficiency is plotted for different phase shift values θ, and for different back-off values γ, whereby FIG. 5a relates to a back-off value of 7.5 dB, FIG. 5b a back-of value of 9 dB, FIG. 5c a back-off value of 11 dB, and FIG. 5d a back-off value of 13 dB. It is noted that in FIGS. 5a to 5d, the dashed black lines represent the drain efficiency for the conventional Doherty power amplifier. In FIG. 5a the curves shown in solid lines represent phase shift values θ of 33°, 39°, 45°, 51°, 57° and 63°, respectively, in ascending order. In FIG. 5b the curves shown in solid lines represent phase shift values θ of 27°, 33°, 39°, 45°, 51° and 57°, respectively, in ascending order. In FIG. 5c the curves shown in solid lines represent phase shift values θ of 23°, 29°, 35°, 41°, 47° and 53°, respectively, in ascending order. In FIG. 5d the curves shown in solid lines represent phase shift values θ of 18°, 24°, 30°, 36°, 42° and 48°, respectively, in ascending order. As can be seen from the graphs, the efficiency degradation at the back-off value can be minimized by proper selection of a phase shift value θ. For γ=7.5 dB and γ=9 dB, by using phase shift values of θ=63° and θ=57°, respectively, an almost flat efficiency profile can be achieved versus back-off. For γ=11 dB and γ 13 dB, by using phase shift values θ=53° and θ=48°, respectively, significantly better efficiency is achieved at back-off compared to a conventional asymmetrical Doherty power amplifier.

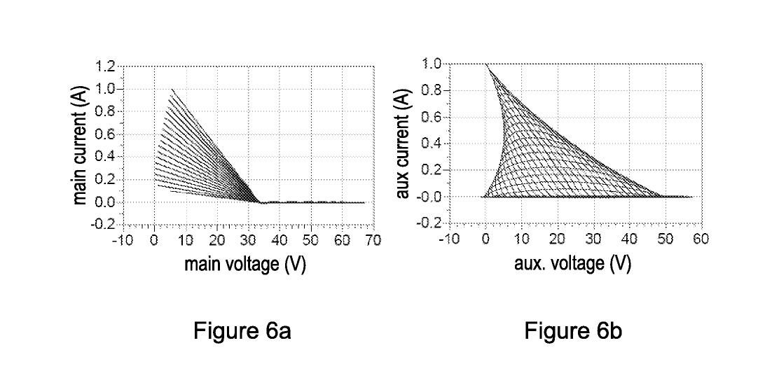

Thus, proper selection of the phase shift value θ essentially enhances the load modulation of the auxiliary power amplifier, improving the efficiency. As an example, FIGS. 6a and 6b show the load lines of the main and auxiliary amplifiers, respectively, for a back-off level γ of 13 dB and a phase shift value θ of 48°.

It is noted that, both for a conventional arrangement and the arrangements proposed by embodiments of the invention, the main drain voltage becomes slightly negative due to imperfect load modulation behaviour in class-B/C Doherty systems, for example as shown in FIGS. 5a to 5d, and as described further in a paper by Paolo Colantonio, et. al., The AB-C Doherty power amplifier. Part II: Validation“, International Journal of RF and Microwave Computer-Aided Engineering, vol. 19, no. 3, pp. 307-316, 2009.

Thus, for a conventional arrangement and also for the arrangements proposed by embodiments of the invention, a slightly higher bias than the nominal value is required for the main amplifier, which can degrade the efficiency slightly.

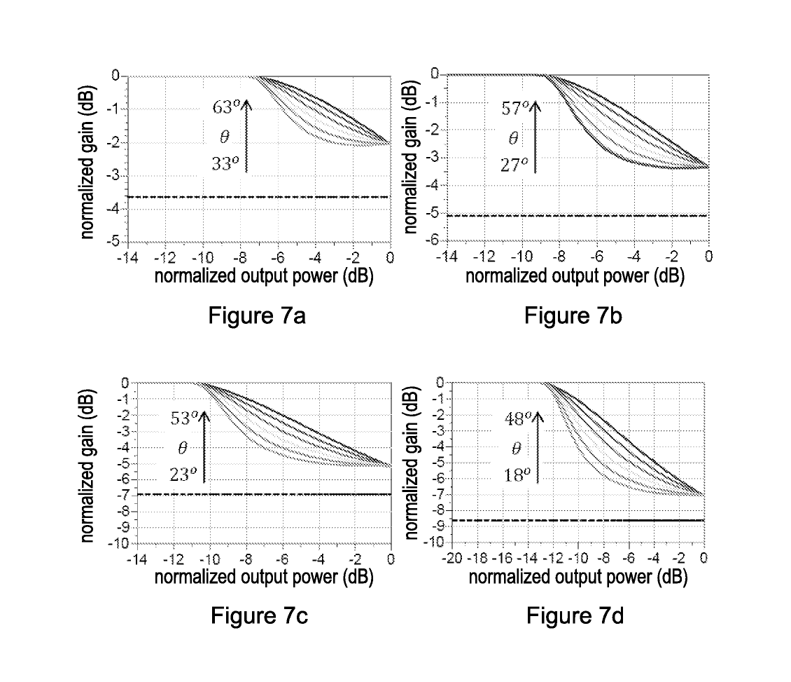

In FIGS. 7a to 7d, the normalized gain of a symmetrical power amplifier arrangement according to an embodiment of the present invention is shown versus back-off for different values (compared to the normalized gain of a conventional asymmetrical Doherty amplifier shown in dashed lines). In particular, FIGS. 7a to 7d show examples where the back-off value γ is 7 dB in FIG. 7a, 9 dB in FIG. 7b, 11 dB in FIGS. 7c, and 13 in FIG. 7d. In FIG. 7a the curves shown in solid lines represent phase shift values θ of 33°, 39°, 45°, 51°, 57° and 63° , respectively, in ascending order. In FIG. 7b the curves shown in solid lines represent phase shift values θ of 27°, 33°, 39°, 45°, 51° and 57°, respectively, in ascending order. In FIG. 7c the curves shown in solid lines represent phase shift values θ of 23°, 29°, 35°, 41°, 47° and 53°, respectively, in ascending order. In FIG. 7d the curves shown in solid lines represent phase shift values θ of 18°, 24°, 30°, 36°, 42° and 48°, respectively, in ascending order.

As can be seen from the graphs, a symmetrical Doherty power amplifier according to an embodiment of the invention provides significantly higher gain compared to a conventional asymmetrical Doherty power amplifier. The gain improvement is typically around 2 dB at peak power level and is even higher at back-off levels. The proposed concept may therefore provide significantly higher power added efficiency performance compared to a conventional Doherty power amplifier. It is noted that a higher gain has the advantage of being able to use smaller pre-drivers before a final output stage of an amplifier arrangement, further improving the overall system efficiency.

Table 1 below shows a ratio of the auxiliary and main device peripheries and the power division ratio, Pᵢₙ₋ₐᵤₓ/Pᵢₙ₋ₘₐᵢₙ, of the input splitter, both for a conventional asymmetrical Doherty power amplifier and a symmetrical Doherty power amplifier according to examples of embodiments of the present invention.

TABLE 1

| | |
|---|---|
| Device periphery ratio | Pᵢₙ₋ₐᵤₓ/Pᵢₙ₋ₘₐᵢₙ |

| | | Proposed | | Proposed |
|---|---|---|---|---|
| | Assym. | symm. | Assym. | symm. |
| γ | Doherty | Doherty | Doherty | Doherty |
| 7.5 dB | 1.65 | 1 | 7.0 dB | 3.5 dB |
| 9 dB | 2.10 | 1 | 7.0 dB | 2.4 dB |
| 11 dB | 2.83 | 1 | 7.4 dB | 1.4 dB |
| 13 dB | 3.75 | 1 | 7.9 dB | 0.9 dB |

As can be seen from Table 1, the power division is more even for the embodiments of the present invention, which has the further advantage of enabling the design and realization of the analog splitter to be simplified. Another advantage is that the terminating impedances are the same for the outputs of the splitter for the proposed symmetrical Doherty power amplifier, thus further simplifying the design of the signal splitting device further.

It is noted that the signal splitting device referred to above may form a module which is separate to the amplifier arrangement itself, as shown in the embodiment of FIG. 1, or may form part of the same integrated circuit as the amplifier arrangement according to another embodiment.

From the above it can be seen that the symmetrical Doherty power amplifiers according to embodiments of the invention have the advantage of providing higher gain and higher back-off efficiency compared to a conventional asymmetrical Doherty power amplifier.

Next, a design example will be provided to help demonstrate how these improvements relate to the performance with realistic communication signals. In this example, a 2 GHz symmetrical Doherty power amplifier is designed for 6.7 dB PAPR wideband code division multiple access (W-CDMA) signals. It is assumed that each of the main and auxiliary amplifiers provides a maximum current of Iₘₐₓ=1A, and is biased at 28 V. The design variable for the back-off level γ is selected as 7.5 dB considering the signal statistics, this being the particular back-off level thus chosen for this example as the back-off level at which efficiency is being optimised.

An ideal voltage controlled current source is used as the transistor model for the simulations. In order to simulate PAE, it is assumed that the transistor technology provides 10 dB of large signal gain for class-B operation, i.e. corresponding to 16 dB of gain for class-A bias. The gain is estimated from a datasheet of a Gallium Nitride High Electron Mobility Transistor (GaN HEMT transistor).

The network parameters are determined by substituting selected values of γ and Iₘₐₓ into the design equations described above. Network parameters also depend on the design variable θ, corresponding to the phase shift between the main and auxiliary branches. Using these assumptions and design parameters, the simulations indicate that the efficiency degradation between the efficiency peaks reduces until the phase shift θ=63°, where an almost flat drain efficiency profile is achieved for 7.5 dB of output power dynamic range. However, although the corresponding S-parameters can easily be realized, for example using lumped element networks via a synthesis method described in the paper by Peter Linnér noted above, no simple equivalent transmission line network is found for that case. On the other hand, if a phase shift θ of 53° is used, calculated S-parameters can easily be realized using a simple transmission line network, and no significant efficiency degradation occurs between the efficiency peaks, as seen from FIGS. 5a to 5d. The corresponding S-parameter matrix follow as:

$$S = [ \begin{matrix}0.56 {e}^{- j {34.2}^{o}} & 0.53 {e}^{- j {169}^{o}} \\ 0.53 {e}^{- j {169}^{o}} & 0.61 {e}^{- j51 {.6}^{o}}\end{matrix} ]$$

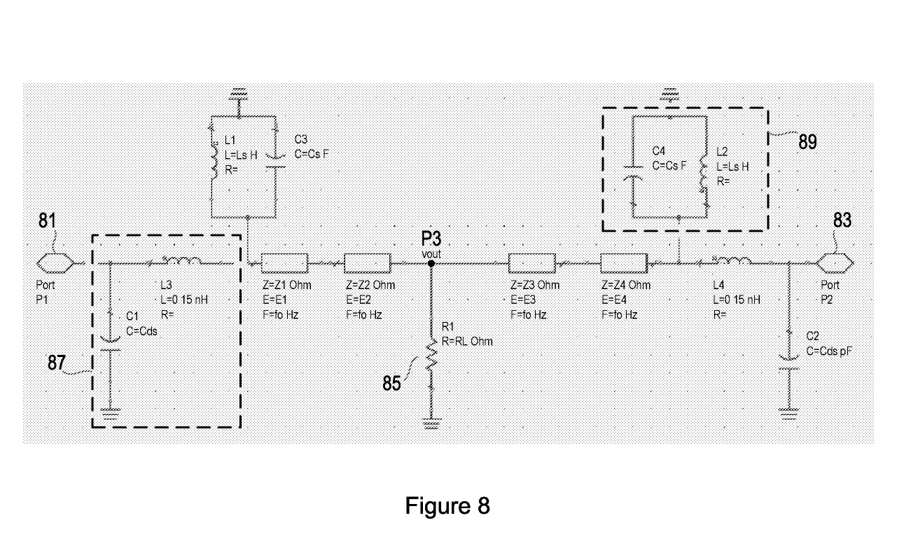

The topology for the load network is found empirically, with an example being shown in FIG. 8. The impedance levels and the electrical angles of the transmission lines are optimized to achieve the best fit versus the calculated S-parameters.

It is noted that, it is desired to fit the network parameters over a frequency band, different topologies might give better results. The topology used in embodiments of the invention may therefore be modified depending on the required RF bandwidth.

For the simulations presented above, the harmonics can be short circuited with a tuned LC resonator, for example the harmonic filter circuit 89 shown in FIG. 8. It is noted, however, that in a more realistic design case, harmonic terminations, for example the second harmonic termination, may be included as a part of the transmission line network. Circuit elements 87 represent the device parasitic.

In the example of the combining network shown in FIG. 8, the port 81 (P1) is coupled to the output of the main amplifier of the amplifier arrangement, the port 83 (P2) coupled to the output of the auxiliary amplifier of the amplifier arrangement, and the node P3 coupled to the load 85 (or system impedance, RL).

The drain efficiency performance achieved with the transmission line combiner is virtually identical to the theoretical results shown in FIG. 5c with θ=53°. The results are therefore not included here again.

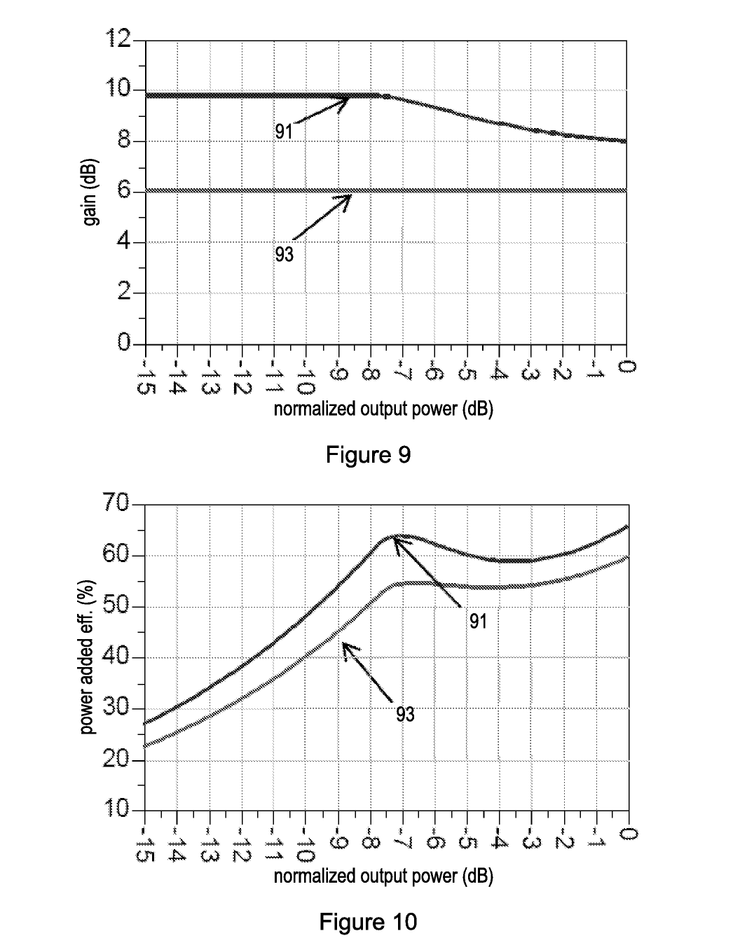

The gain results are shown in FIG. 9, with reference 91 representing the gain of an amplifier arrangement according to an embodiment of the invention, and reference 93 representing the gain of a conventional asymmetrical Doherty amplifier. As seen from FIG. 9, a symmetrical Doherty power amplifier according to an embodiment of the invention provides around 8 dB gain at peak power level and the gain expands to 9.8 dB at 7.5 dB back off. The conventional asymmetrical Doherty power amplifier provides around 6 dB of flat gain with the same transistor performance, which is very low for most of the practical applications. However, it is also noted that, these gain results are achieved by directly following the theoretical formulations. In practice, the inherent low gain problem of the conventional asymmetrical Doherty power amplifiers is often circumvented by biasing the main cell in class-AB operation instead, and/or reducing the size of the class-C cell, for example as explained in a paper by Steve C. Cripps, “Advanced Techniques in RF Power Amplifier Design”, Artech House, 2002 . Although such approaches may solve the problem of low gain in a conventional Doherty amplifier, they will also violate the ideal operation of the circuit, significantly degrading the drain efficiency. For instance, the latter approach is named Doherty Lite by Cripps, emphasizing the resulting performance degradation in efficiency. As such, the embodiments of the invention enable the gain to be increased at back-off levels without suffering from such disadvantages.

Referring to FIG. 10, this shows power added efficiency results 91 for an embodiment of the invention, where also the results achieved with a conventional Doherty power amplifier are shown as reference 93 for comparison purposes. As seen from FIG. 10, a symmetrical Doherty power amplifier according to an embodiment of the invention results in significantly higher PAE at back-off compared to the conventional approach due to its significantly higher gain. For example, more than 9% of better PAE is achieved at a back-off level of 9 dB, with this improvement being reflected in the average PAE results. The symmetrical Doherty power amplifier according to embodiments of the invention provides an average PAE of 57% with a 6.7 dB PAPR W-CDMA signals, while an average PAE of 50.4% is achieved with a conventional asymmetrical Doherty power amplifier, as shown in Table 2 below. It is noted that this significant improvement will be further multiplied when considering overall power consumption of a radio base station transmitter.

Table 2 below shows the benchmarking of symmetrical and asymmetrical Doherty power amplifiers, for an example using a test signal corresponding to a 6.7 dB PAPR W-CDMA Signal.

TABLE 2

| PA Type | $\frac{{P}_{in \text{-} aux}}{{P}_{in \text{-} main}}$ | PUF | Avg. |
|---|---|---|---|
| Asymmetrical | 7 dB | 0.112 | 50.5% |
| Doherty | | | |
| Symmetrical | 3.5 dB | 0.117 | 57% |
| Doherty | | | |

It is also noted that the power utilization factor (PUF), is higher for the symmetrical Doherty power amplifier according to embodiments of the invention, as shown in Table 2. This has the advantage that the same output power can be achieved with smaller total device size, reducing the device parasites and cost.

Thus, simulation results clearly prove that a symmetrical Doherty power amplifier according to embodiments of the invention offer better efficiency performance compared to asymmetrical Doherty power amplifiers with a more practical configuration. The higher performance and flexibility offered by the embodiments of the invention therefore makes them suited, for example, for low/medium level output power systems, such as small base stations, microwave links, and handsets.

The embodiments of the invention have the advantage of providing higher drain efficiency at back-off.

Furthermore, the phase off-set between the main and auxiliary branches provides a new additional degree of freedom in the new proposed concept. By proper selection of the phase off-set, an almost flat efficiency profile can be achieved for a large range of output power levels (for example a range of 9-10 dB).

The embodiments enable higher gain to be achieved as follows. The main and auxiliary transistors have the same size for the new symmetrical Doherty concept, independent of the PAPR. Thus, the need for a very large class-C amplifier is therefore eliminated. This significantly improves the gain, enabling higher power added efficiency. Moreover, smaller pre-drivers can be used before the final output stage, further improving the overall efficiency of the transmitter.

Higher power utilization factor is also achievable, since the use of very large class-C amplifiers is avoided, thus making the overall power utilization factor of the power amplifier higher compared to asymmetrical Doherty amplifiers. This allows smaller devices to be used for the same output power level, thus also having the advantage of reducing the device parasites (which may in turn also help improve the RF bandwidth).

For hybrid realization of asymmetrical Doherty power amplifiers, the required optimal device periphery ratios are typically not available. Thus, the embodiments of the invention, having equally sized transistors, provide a more practical transistor configuration, and eliminate this issue since symmetrical devices are used for main and auxiliary cells.

Furthermore, the embodiments of the invention enable simpler realization of an analog power splitter to be provided. Since the class-B and class-C amplifiers have the same device periphery, power division is less uneven for the embodiments of the invention. This is a distinct advantage for realization of the analog splitter. Moreover, it also means that the terminating impedances are the same for the outputs of the splitter, further simplifying its design.

A phase adjusting module for adjusting the phase offset value (θ) between the first signal and the second signal to a desired value may be provided, for example as part of the signal splitting module, as part of the amplifier arrangement itself, or as part of some other functional module. The phase offset value can therefore be selected according to desired operating parameters, and components of the combining network adjusted or altered accordingly, including the possibility of a dynamically adjustable configuration.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single processor or other unit may fulfil the functions of several units recited in the claims. Any reference signs in the claims shall not be construed so as to limit their scope.

1. An amplifier arrangement for optimising efficiency at a peak power level and a back-off power level, the amplifier arrangement comprising:
a main power amplifier provided in a main branch for receiving a first signal, the main power amplifier being configured to operate in a class-B mode of operation;
an auxiliary power amplifier provided in an auxiliary branch for receiving a second signal, the auxiliary power amplifier being configured to operate in a class-C mode of operation;
wherein the main power amplifier and the auxiliary power amplifier are substantially matched in size, and wherein the received first and second signals have a phase offset value (θ) that is selected in relation to a particular back-off power level (γ) of operation, wherein 0<θ<180°; and
a combining network configured to couple the output signals of the main and auxiliary amplifiers to an output node of the amplifier arrangement such that the output of the auxiliary power amplifier load modulates the output of the main power amplifier, wherein the circuit element values of the combining network are derived based on the selected phase shift value (θ) and the related back-off power level (γ) at which the amplifier arrangement is optimised for efficiency.

2. The amplifier arrangement as claimed in claim 1, wherein the circuit element values of the combining network are derived based on desired operating conditions which include:
presenting an optimal load to the main power amplifier at the peak power level;
presenting an optimal load to the auxiliary amplifier at the peak power level; and
presenting optimal load to the main power amplifier at the particular back-off level.

3. The amplifier arrangement as claimed in claim 1, wherein the combining network comprises a three port network comprising a first port connected to the output of main power amplifier, a second port connected to the output of auxiliary power amplifier, and a third port connected to the output node.

4. The amplifier arrangement as claimed in claim 3, wherein the circuit element values of the three port network are determined using a two port network model.

5. The amplifier arrangement as claimed in claim 4, wherein network parameters of the two port network model are derived only in terms of transistor technology parameters and design variables corresponding to the particular back-off level (γ) and the phase shift value (θ).

6. The amplifier arrangement as claimed in claim 1, further comprising a signal splitting device configured to receive an input signal (102), wherein the signal splitting device is configured to split the input signal into the first signal for the main branch and the second signal for the auxiliary branch of the amplifier arrangement.

7. The amplifier arrangement as claimed in claim 1, further comprising a phase adjusting module for adjusting the phase offset value (θ) between the first signal and the second signal.

8. A method of optimising the efficiency of an amplifier arrangement at a peak power level and a back-off power level, the method comprising:
amplifying a first signal using a main power amplifier configured to operate in a class-B mode of operation;
amplifying a second signal using an auxiliary power amplifier configured to operate in a class-C mode of operation;
wherein the main power amplifier and the auxiliary power amplifier are substantially matched in size, and wherein the first signal and the second signal have a phase offset value (θ) that is selected in relation to a particular back-off power level (γ) of operation, wherein 0<θ<180°; and
combining the output signals of the main and auxiliary amplifiers to an output node of the amplifier arrangement using a combining network, such that the output of the auxiliary power amplifier load modulates the output of the main power amplifier, wherein the circuit element values of the combining network are derived based on the selected phase shift value (θ) and the related back-off power level (γ) at which the amplifier arrangement is optimised for operation.

9. The method as claimed in claim 8, wherein combining the output signals further comprises:
presenting an optimal load to the main power amplifier at the peak power level;
presenting an optimal load to the auxiliary amplifier at the peak power level; and
presenting an optimal load to the main power amplifier at the particular back-off level (γ).

10. The method as claimed in claim 8, wherein the combining network comprises a three port network comprising a first port connected to the output of main amplifier, a second port connected to the output of auxiliary amplifier, and a third port connected to the output node of the amplifier arrangement.

11. The method as claimed in claim 10, wherein deriving the circuit element values of the three port network comprises using a two port network model to determine an initial set of network parameters, and converting the two port network parameters to the three port network, and deriving the circuit element values of the three port network accordingly.

12. The method as claimed in claim 11, further comprising determining if the derived circuit element values of the three port network can be realised using a lumped component circuit topology and/or a transmission line network topology, and, if not, selecting a different phase shift value θ and repeating the derivation of the circuit element values of the three port network based on the different phase shift value θ.

13. The method as claimed in claim 11, wherein using a two-port network model to determine network parameters of the combining network comprises defining an impedance matrix for the two port network:
$$[ \begin{matrix}{V}_{m} \\ {V}_{a}\end{matrix} ] = [ \begin{matrix}{Z}_{11} & {Z}_{12} \\ {Z}_{21} & {Z}_{22}\end{matrix} ] [ \begin{matrix}{I}_{m} \\ {I}_{a}\end{matrix} ]$$
whereby Z₁₂=Z₂₁, and whereby Vm and Im represent the voltage across and the current flowing through the main power amplifier, and Va and la the voltage across the power flowing through the auxiliary power amplifier.

14. The method as claimed in claim 13, further comprising solving the following equations to derive the network parameters of the two port network:
$${Z}_{11} = \frac{{V}_{BR}}{2 {v}_{bk} \vert {I}_{m} \vert}$$
$${Z}_{12} = \frac{{e}^{j θ} ( {v}_{bk} - 1 ) {V}_{BR}}{2 {v}_{bk} \vert {I}_{a} \vert}$$
$${Z}_{22} = \frac{{V}_{BR} ( - {e}^{j 2 θ} \vert {I}_{m} \vert ( {v}_{bk} - 1 ) + {v}_{bk} {I}_{a} )}{2 {v}_{bk} {\vert {I}_{a} \vert}^{2}}$$
where V_{BR} represents the respective breakdown voltage of a transistor of the main power amplifier and auxiliary power amplifier, respectively, and v_{bk} represents the main input voltage, vi, level at which the output power is at the desired back-off level.

15. The method as claimed in claim 8, further comprising controlling the main power amplifier and the auxiliary power amplifier to deliver maximum possible output power at a peak power level, and to fully utilize the current and voltage swings available from both the main power amplifier and auxiliary power amplifier.
